(19) United States
(12) Patent Application Publication
(10) Pub. No.: US 2026/0130205 A1
(43) Pub. Date: May 7, 2026

(54) SEMICONDUCTOR STRUCTURE AND METHOD FOR FORMING SAME

(71) Applicant: CXMT Corporation, Hefei (CN)

(72) Inventor: Chih-Cheng Liu, Hefei (CN)

(73) Assignee: CXMT Corporation, Hefei (CN)

(21) Appl. No.: 19/382,833

(22) Filed: Nov. 7, 2025

Related U.S. Application Data
(63) Continuation of application No. PCT/CN2024/089972, filed on Apr. 26, 2024.

(30) Foreign Application Priority Data
May 24, 2023 (CN) 202310613877.7

(51) Int. Cl. H01L 23/528; H01L 21/768; H01L 23/522

(52) U.S. Cl. CPC H10W 20/435; H10W 20/089; H10W 20/42; H10W 20/43

(57) ABSTRACT

Provided are a semiconductor structure and a method for forming the same. The semiconductor structure includes a substrate, a signal line located on the substrate, and a contact structure extending along a first direction. The contact structure is disposed partially around an end part of the signal line, the contact structure is in contact with and electrically connected to the signal line, and the first direction is perpendicular to a top surface of the substrate.

The present application is a continuation of International Patent Application No. PCT/CN2024/089972, filed on Apr. 26, 2024, which claims priority to Chinese Patent Application No. 202310613877.7 filed with China National Intellectual Property Administration on May 24, 2023 and entitled “SEMICONDUCTOR STRUCTURE AND METHOD FOR FORMING SAME”, the content of which is incorporated herein by reference in their entireties.

### TECHNICAL FIELD

The present disclosure relates to the technical field of semiconductor manufacturing, and particularly, to a semiconductor structure and a method for forming the same.

### BACKGROUND

A dynamic random access memory (DRAM) is a commonly used semiconductor apparatus in electronic devices, such as computers. It is composed of a plurality of memory cells, and each memory cell typically includes a transistor and a capacitor. A gate of the transistor is electrically connected to a word line, a source of the transistor is electrically connected to a bit line, and a drain of the transistor is electrically connected to a capacitor. The word line voltage on the word line can control switching-on/off of the transistor, such that data information stored in the capacitor can be read from the capacitor via the bit line, or data information can be written into the capacitor via the bit line.

In a semiconductor structure (such as a DRAM), a signal line, such as a word line or a bit line needs to be led out via a contact structure so as to facilitate electrical connection with an external control circuit. The contact structure is usually landed on the top surface of a signal line, such as a word line or a bit line. However, as the size of the semiconductor structure, such as the DRAM, continues to shrink, the contact area between the contact structure and the signal line, such as the word line and the bit line, continues to decrease, such that the contact resistance between the contact structure and the signal line greatly increases, thereby reducing the performance of the semiconductor structure.

Therefore, how to reduce the contact resistance inside the semiconductor structure and thus improve the performance of the semiconductor structure is an urgent technical problem to be solved at present.

### SUMMARY

Some embodiments of the present disclosure provide a semiconductor structure and a method for forming the same.

According to some embodiments, the present disclosure provides a semiconductor structure. The semiconductor structure includes: a substrate; a signal line located on the substrate; and a contact structure extending along a first direction, where the contact structure is disposed partially around an end part of the signal line, the contact structure is in contact with and electrically connected to the signal line, and the first direction is perpendicular to a top surface of the substrate.

According to some other embodiments, the present disclosure further provides a method for forming a semiconductor structure. The method includes the following steps: providing a substrate; forming a signal line on the substrate; and forming a contact structure extending along a first direction, where the contact structure is disposed partially around an end part of the signal line, the contact structure is in contact with and electrically connected to the signal line, and the first direction is perpendicular to a top surface of the substrate.

### BRIEF DESCRIPTION OF DRAWINGS

FIG. 1 is a schematic top view of a semiconductor structure according to an embodiment of the present disclosure;

FIG. 2 is a schematic cross-sectional view taken along line A-A in FIG. 1;

FIG. 3 is a schematic cross-sectional view taken along line B-B in FIG. 1;

FIG. 4 is a schematic diagram of a positional relationship between part of a contact structure and a signal line according to an embodiment of the present disclosure, the part of the contact structure being disposed around a side wall of the signal line;

FIG. 5 is a flowchart of a method for forming a semiconductor structure according to an embodiment of the present disclosure;

FIG. 6, FIG. 7, FIG. 8 and FIG. 9 are schematic diagrams of main process structures in a process of forming a semiconductor structure according to an embodiment of the present disclosure; and

FIG. 10, FIG. 11, FIG. 12 and FIG. 13 are schematic diagrams of various positional relationships between a contact structure and a signal line according to an embodiment of the present disclosure.

### DETAILED DESCRIPTION OF EXAMPLE EMBODIMENTS

Embodiments of the semiconductor structure and the method for forming the same provided by the present disclosure will be described in detail below with reference to the accompanying drawings.

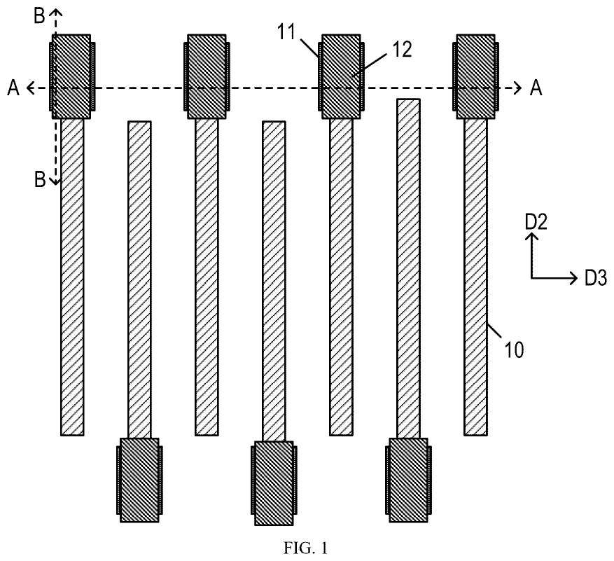

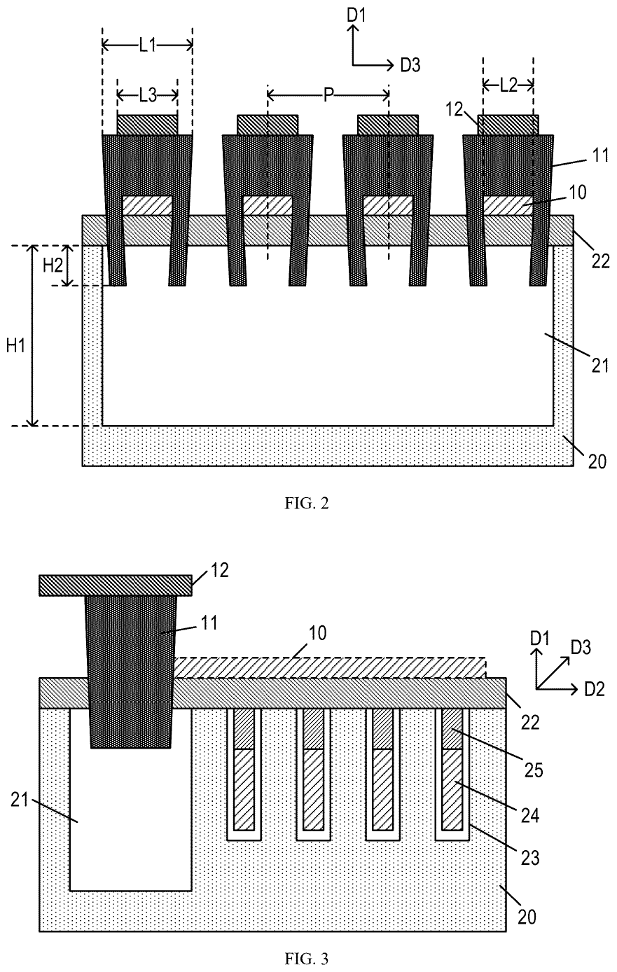

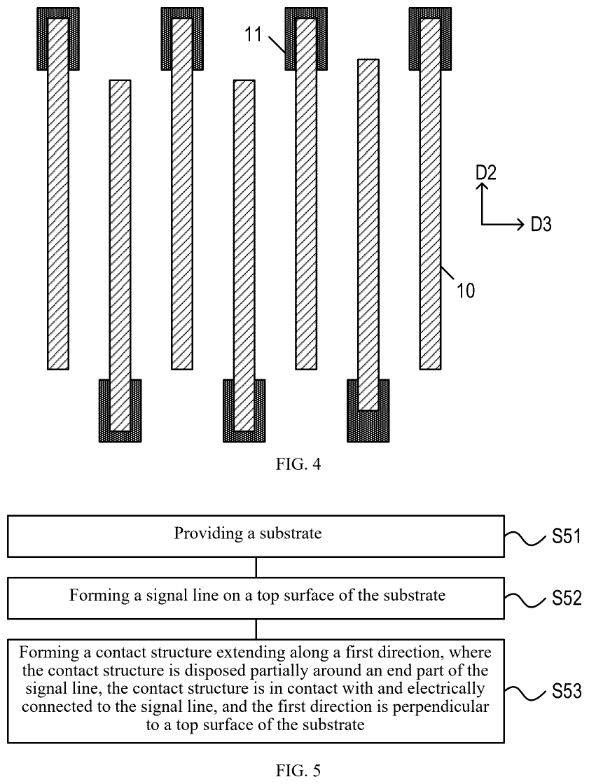

Embodiments of the present disclosure provide a semiconductor structure. FIG. 1 is a schematic top view of a semiconductor structure according to an embodiment of the present disclosure, FIG. 2 is a schematic cross-sectional view taken along line A-A in FIG. 1, and FIG. 3 is a schematic cross-sectional view taken along line B-B in FIG. 1. As shown in FIG. 1 to FIG. 3, the semiconductor structure includes:
a substrate 20;
a signal line 10 located on the substrate 20; and
a contact structure 11 extending along a first direction D1. The contact structure 11 is disposed around an end part of the signal line 10, the contact structure 11 is in contact with and electrically connected to the signal line 10, and the first direction D1 is perpendicular to a top surface of the substrate 20.

The semiconductor structure described in the embodiments of the present disclosure may be, but is not limited to, a DRAM. An embodiment in which the semiconductor structure is a DRAM will be taken as an example for description below. The substrate 20 may be, but is not limited to, a silicon substrate. In the embodiments of the present disclosure, a case in which the substrate 20 is a silicon substrate will be taken as an example for description below. In other embodiments, the substrate 20 may also be a gallium nitride substrate, a gallium arsenide substrate, a gallium carbide substrate, a silicon carbide substrate, an SOI substrate, or other semiconductor substrates. The substrate 20 is configured to support a device structure thereon. Taking the semiconductor structure being a DRAM as an example, the semiconductor structure includes a plurality of memory cells, the signal line 10 is located on a top surface of the substrate 20, and the signal line 10 is electrically connected to the memory cells. One end of the contact structure 11 (for example, a bottom of the contact structure 11) is in contact with and electrically connected to the signal line 10, and the other end of the contact structure 11 (for example, a top of the contact structure 11) is electrically connected to a peripheral control circuit. A control signal from the peripheral control circuit is transmitted to the memory cell via the contact structure 11 and the signal line 10 sequentially. In an example, the bottom of the contact structure 11 is disposed opposite to the top of the contact structure 11 along the first direction D1.

That the contact structure 11 is disposed partially around the end part of the signal line 10 means that the contact structure 11 is disposed partially around a side wall of the end part of the signal line 10. In the embodiments of the present disclosure, the contact structure 11 is arranged to be disposed partially around the end part of the signal line 10 to increase the contact area between the contact structure 11 and the signal line 10, such that the contact resistance between the contact structure 11 and the signal line is reduced, and the performance of the semiconductor structure is improved.

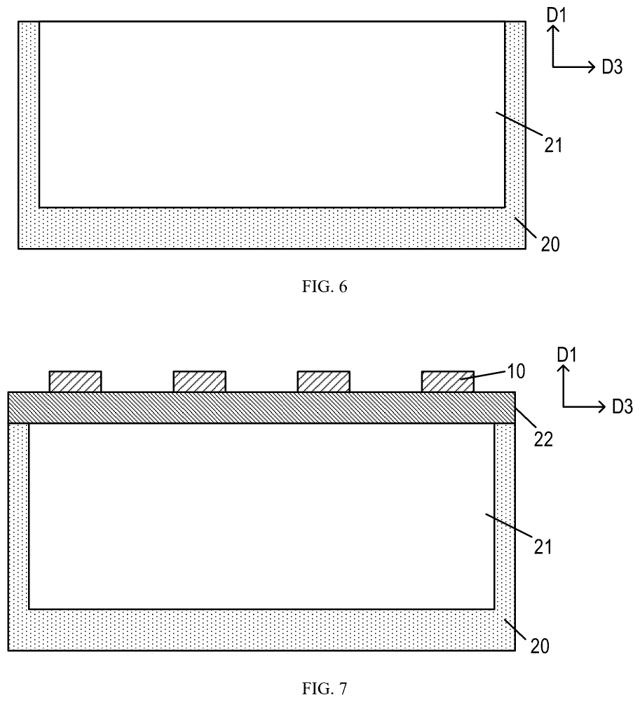

FIG. 4 is a schematic diagram of a positional relationship between part of the contact structure and the signal line according to an embodiment of the present disclosure, the part of the contact structure being disposed around the side wall of the signal line. In some embodiments, the cross-section of at least part of the bottom of the contact structure 11 is U-shaped.

For example, as shown in FIG. 4, that the cross-section of at least part of the bottom of the contact structure 11 is U-shaped means that the projection, on the top surface of the substrate 20, of the contact structure 11 that is located at the end part of the signal line 10 and located on the side wall of the signal line 10 is U-shaped. By configuring at least part of the cross-section of the bottom of the contact structure 11 to be U-shaped, the bottom of the contact structure 11 partially surrounds the side wall of the signal line 10, thereby further increasing the contact area between the contact structure 11 and the signal line 10, and further reducing the contact resistance inside the semiconductor structure.

In some embodiments, the signal line 10 extends along a second direction D2, and the second direction D2 is parallel to the top surface of the substrate 20.

The contact structure 11 covers a top surface of the signal line 10 and is disposed around part of the side wall of the signal line 10.

For example, as shown in FIG. 1 to FIG. 4, the bottom of the contact structure 11 continuously covers the top surface of the signal line 10 and the side wall of the signal line 10, and the bottom of the contact structure 11 is also disposed around part of the side wall of the signal line 10, thereby further increasing the contact area between the contact structure 11 and the signal line. This not only further ensures the stable electrical connection between the contact structure 11 and the signal line 10, but also further reduces the contact resistance inside the semiconductor structure.

In some embodiments, a width of the contact structure 11 located on the top surface of the signal line 10 along a third direction D3 is a first width L1, a width of the signal line 10 along the third direction D3 is a second width L2, the first width L1 is greater than or equal to the second width L2, the third direction D3 is parallel to the top surface of the substrate 20, and the second direction D2 intersects with the third direction D3. With this structure, the contact structure 11 can continuously cover the entire top surface of the end part of the signal line 10 along the second direction D2 and the side wall of the end part of the signal line 10 along the second direction D2, thereby further increasing the contact area between the signal line 10 and the contact structure 11 and further reducing the contact resistance between the signal line 10 and the contact structure 11; moreover, the manufacturing process of the contact structure 11 can be simplified, thereby reducing the manufacturing difficulty of the contact structure 11.

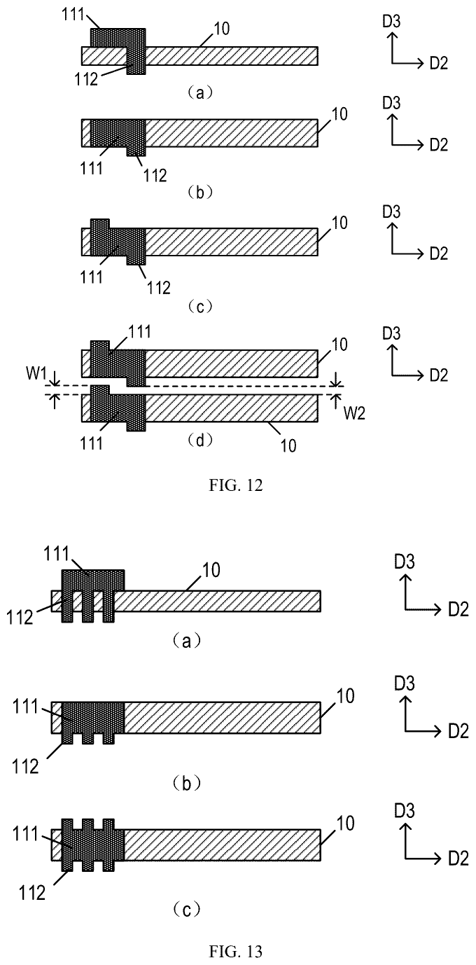

FIG. 10 to FIG. 13 are schematic diagrams of various positional relationships between a contact structure and a signal line according to an embodiment of the present disclosure. In some embodiments, the contact structure 11 includes:
a main body portion 111 located on the signal line 10 and being in contact with and electrically connected to the signal line 10; and
an extension portion 112 disposed at an end part of the main body portion 111 along the second direction D2 and being in contact with and electrically connected to the main body portion 111. The extension portion 112 covers the end surface of the signal line 10, such that a cross-section of the entire contact structure 11 is L-shaped, thereby facilitating further simplification of the manufacturing process of the contact structure 11. In an example, a width of the main body portion 111 along the third direction D3 is less than a width of the signal line 10 along the third direction D3, as shown in FIG. 10, where (a) of FIG. 10 is a schematic cross-sectional view of the contact structure and the signal line in the semiconductor structure, and (b) of FIG. 10 is a schematic top view of the contact structure and the signal line in the semiconductor structure.

In some embodiments, the contact structure 11 includes:
a main body portion 111 located on the signal line 10 and being in contact with and electrically connected to the signal line 10; and
an extension portion 112 disposed at an end part of the main body portion 111 along the third direction D3 and being in contact with and electrically connected to the main body portion 111. The extension portion 112 covers a side wall of the signal line 10, as shown in FIG. 11, FIG. 12, and FIG. 13, where (a) of FIG. 11, (a) of FIG. 12, and (a) of FIG. 13 are all schematic cross-sectional diagrams of the contact structure and the signal line in the semiconductor structure, and (b) of FIG. 11, (c) of FIG. 11, (b) of FIG. 12, (c) of FIG. 12, (b) of FIG. 13, and (c) of FIG. 13 are all schematic top views of the contact structure and the signal line in the semiconductor structure.

In some embodiments, a plurality of the extension portions 112 are spaced apart along the second direction D2 and are all in contact with and electrically connected to the main body portion 111, so as to relieve the stress inside the semiconductor structure and improve the reliability of the semiconductor structure;

a plurality of the extension portions 112 are disposed on two opposite sides of the main body portion 111 along the third direction D3, as shown in (a) of FIG. 13 and (c) of FIG. 13.

In an example, as shown in (a) of FIG. 11, (a) of FIG. 12, and (a) of FIG. 13, the main body portion 111 covers the top surface of the signal line 10, and the extension portion 112 may be connected to one end of the main body portion 111 along the third direction D3 (as shown in (b) of FIG. 11, (b) of FIG. 12, and (b) of FIG. 13) to save the space occupied by the contact structure 11; or the extension portion 112 may be connected to two opposite ends of the main body portion 111 along the third direction D3 (as shown in (c) of FIG. 11, (c) of FIG. 12, and (c) of FIG. 13) to further increase the contact area between the contact structure 11 and the signal line 10 and further reduce the contact resistance between the contact structure 11 and the signal line 10. In an example, when the relative positional relationship between the extension portion 112 and the main body portion 111 in the contact structure 11 is as shown in (c) of FIG. 12, the width of the extension portion 112 along the third direction D3 is a first width W1; for two signal lines 10 adjacent along the third direction D3, a gap between the extension portion 112 in the contact structure 11 on one of the signal lines 10 and the other signal line 10 along the third direction D3 has a second width W2, and the second width W2 is less than or equal to the first width W1, as shown in (d) of FIG. 12, so as to further improve the integration level of the semiconductor structure. The (d) of FIG. 12 shows two signal lines 10 spaced apart along the third direction D3.

In some embodiments, as shown in FIG. 4, a plurality of the signal lines 10 are spaced apart along the third direction D3, a plurality of the contact structures 11 are electrically connected to the plurality of the signal lines 10 in a one-to-one correspondence, and each of the contact structures 11 is disposed partially around an end part of the signal line 10 electrically connected thereto.

The contact structures 11 electrically connected to two adjacent signal lines 10 are staggered along the third direction D3.

For example, the semiconductor structure includes a plurality of the signal lines 10 spaced apart along the third direction D3, and a plurality of the contact structures are electrically connected to the plurality of the signal lines 10 in a one-to-one correspondence, such that control signals are transmitted to the plurality of the signal lines 10 via the plurality of the contact structures, respectively. Allowing the contact structures 11 electrically connected to two adjacent signal lines 10 along the third direction D3 to be staggered along the third direction D3 can increase the distance along the third direction D3 between two contact structures 11 electrically connected to two adjacent signal lines 10 along the third direction D3, reduce the capacitive coupling effect between two contact structures 11 electrically connected to two adjacent signal lines 10 along the third direction D3, and reduce or even avoid the signal crosstalk between two adjacent signal lines 10.

In some embodiments, a plurality of the signal lines 10 are sequentially arranged in the third direction D3, and the contact structure 11 electrically connected to an odd-numbered signal line 10 and the contact structure 11 electrically connected to an even-numbered signal line 10 are disposed opposite to each other along the second direction D2.

Specifically, two contact structures 11 electrically connected to two adjacent signal lines 10 are disposed opposite to each other along the second direction D2. In one aspect, the distance between two adjacent contact structures 11 along the third direction D3 can be further increased, thereby further reducing the capacitive coupling effect between two adjacent contact structures 11 along the third direction D3; in another aspect, the process window for forming the contact structures 11 can be widened, the manufacturing difficulty of the contact structures 11 can be reduced, and the manufacturing efficiency of the semiconductor structure can be improved.

In some embodiments, a first spacing P is present between adjacent signal lines 10 along the third direction D3, and half of the first width L1 is less than one third of the first spacing P. With this structure, in one aspect, it can be ensured that two adjacent contact structures 11 along the third direction D3 are fully isolated, and signal crosstalk between two adjacent contact structures 11 is fully reduced; in another aspect, it also helps to control the size of the semiconductor structure, thereby laying a foundation for miniaturization of the semiconductor structure.

In some embodiments, in the first direction D1, a bottom surface of the contact structure 11 is located below a bottom surface of the signal line 10. For example, as shown in FIG. 2, in the first direction D1, the contact structure 11 extends below the signal line 10, such that the contact structure 11 can sufficiently cover the side wall of the signal line 10, thereby further increasing the contact area between the contact structure 11 and the signal line 10 and reducing the contact resistance between the contact structure 11 and the signal line 10.

In some embodiments, the semiconductor structure further includes:
a dielectric layer 22 located on the top surface of the substrate 20. The signal line 10 is located on the top surface of the dielectric layer 22, and the contact structure 11 penetrates through the dielectric layer 22 along the first direction D1.

In some embodiments, the substrate 20 further includes therein an active region and an isolation region 21 located outside the active region.

The contact structure 11 extends to the inside of the isolation region 21 along the first direction D1.

A case in which the semiconductor structure is a DRAM will be taken as an example for description below. The substrate 20 includes therein a memory area and a peripheral area, and the memory area includes the active region for forming a memory cell. The isolation region 21 may be located between the memory area and the peripheral area, and is configured to isolate the memory area from the peripheral area. The dielectric layer 22 covers the top surface of the substrate 20, and a projection of the dielectric layer 22 on the top surface of the substrate 20 covers the memory area and the isolation region 21. The signal line 10 is located on a top surface of the dielectric layer 22 (i.e., a surface of the dielectric layer 22 facing away from the substrate 20), and is electrically connected to the active region in the substrate 20 via a contact plug penetrating through the dielectric layer 22. In an example, the isolation region 21 may be made of an oxide material, such as silicon dioxide. The dielectric layer 22 may be made of an insulation dielectric material, such as an oxide material, a nitride material, or an oxynitride material.

In some embodiments of the present disclosure, the contact structure 11 is arranged to penetrate through the dielectric layer 22 along the first direction D1 and extend to the inside of the isolation region 21, such that the contact area between the contact structure 11 and the signal line 10 can be further increased, and the contact resistance between the contact structure 11 and the signal line 10 can be reduced; at the same time, the stable contact and electrical connection between the contact structure 11 and the side wall of the signal line 10 can be ensured, and the overall stability of the contact structure 11 can be improved.

In some embodiments, a depth of the isolation region 21 along the first direction D1 inside the substrate 20 is a first depth H1, a depth of the contact structure 11 extending along the first direction D1 to the isolation region 21 is a second depth H2, and the second depth H2 is less than the first depth H1.

In some embodiments, the second depth H2 is less than or equal to a quarter of the first depth H1.

Specifically, by defining the second depth H2 to be less than or equal to a quarter of the first depth H1, in one aspect, the etching depth when the contact structure 11 is formed can be reduced, thereby further simplifying the process of forming the contact structure 11 and improving the efficiency of forming the contact structure 11; in another aspect, the problem of current leakage caused by the contact structure 11 being too close to the substrate 20 below the isolation region 21 (i.e., the well region inside the substrate 20) can also be avoided, thereby further ensuring the yield of the semiconductor structure.

In some embodiments, the semiconductor structure further includes:
an interconnect metal layer 12 located on a top surface of the contact structure 11 and electrically connected to the contact structure 11. A width of the interconnect metal layer 12 along the third direction D3 is a third width L3, and the third width L3 is less than or equal to the first width L1.

Specifically, the width of the contact structure 11 on the top surface of the signal line 10 along the third direction (i.e., the first width L1) is greater than the width of the signal line 10 along the third direction D3 (i.e., the second width L2), such that when the interconnect metal layer 12 is formed, the process window for forming the interconnect metal layer 12 can be widened, and the manufacturing process of the interconnect metal layer 12 can be simplified. The interconnect metal layer 12 is configured to electrically connect the contact structure 11 and a peripheral control circuit.

In some embodiments, the semiconductor structure is a DRAM, and the signal line 10 is a bit line or a word line.

In an example, the substrate 20 includes therein a plurality of buried word line structures spaced apart along the second direction D2 and extending along the third direction D3. The word line structure includes a word line trench 23 extending from the top surface of the substrate 20 to the inside of the substrate 20 along the first direction D1, a word line conductive layer 24 filled in the word line trench 23, and a word line cap layer 25 filled in the word line trench 23 and covering a top surface of the word line conductive layer 24, as shown in FIG. 3. The dielectric layer 22 covers the top surface of the substrate 20, and the signal line 10 as a bit line is located on the top surface of the dielectric layer 22. From the view angle as shown in FIG. 3, the signal line 10 should not be visible. In order to clearly show the relative positional relationship between the signal line 10 and the contact structure 11, the position of the signal line 10 is shown by a dashed line.

In another example, the substrate 20 includes therein a plurality of buried bit lines spaced apart along the second direction D2 and extending along the third direction D3. The dielectric layer 22 covers the top surface of the substrate 20, and the signal line 10 as a word line is located on the top surface of the dielectric layer 22.

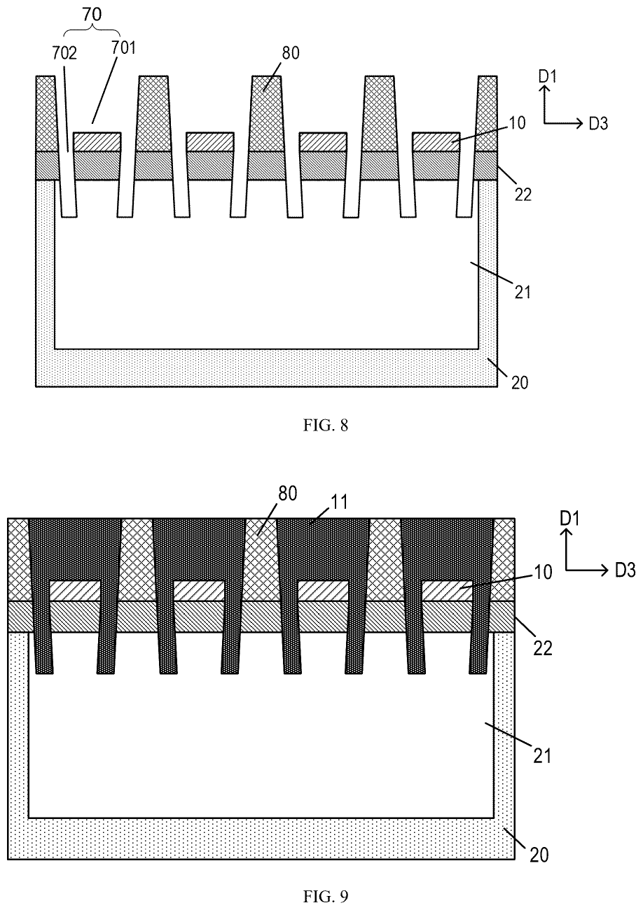

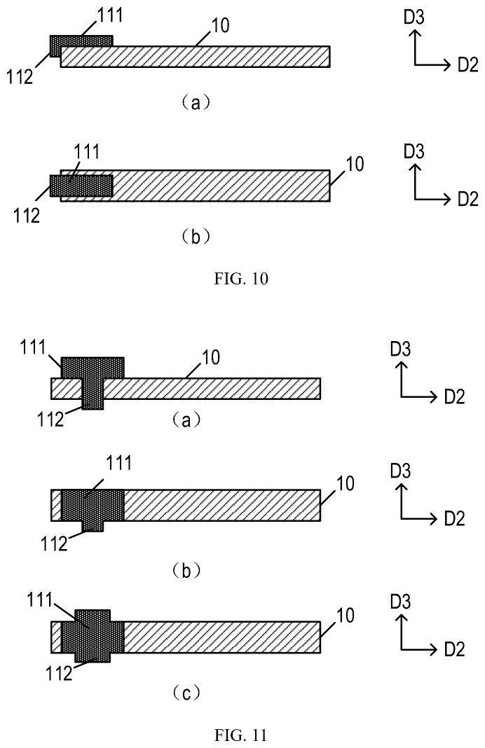

Embodiments of the present disclosure further provide a method for forming a semiconductor structure. FIG. 5 is a flowchart of a method for forming a semiconductor structure according to an embodiment of the present disclosure, and FIG. 6 to FIG. 9 are schematic diagrams of main process structures in a process of forming a semiconductor structure according to an embodiment of the present disclosure. For a schematic diagram of the semiconductor structure formed in the embodiments of the present disclosure, please refer to FIG. 1 to FIG. 4. As shown in FIG. 1 to FIG. 9, the method for forming a semiconductor structure includes the following steps.
In step S51, a substrate 20 is provided, as shown in FIG. 6.
In step S52, a signal line 10 is formed on the substrate 20, as shown in FIG. 7.
In step S53, a contact structure 11 extending along a first direction D1 is formed. The contact structure 11 is disposed partially around an end part of the signal line 10, and the contact structure 11 is in contact with and electrically connected to the signal line 10, and the first direction D1 is perpendicular to a top surface of the substrate 20, as shown in FIG. 1 to FIG. 4 and FIG. 9.

In some embodiments, the specific steps of forming the signal line 10 on the top surface of the substrate 20 include:
forming a dielectric layer 22 on the top surface of the substrate 20; and
forming the signal line 10 on a top surface of the dielectric layer 22.

A embodimentin which the semiconductor structure is a DRAM and the signal line 10 is a bit line will be taken as an example for description below. The substrate 20 may be, but is not limited to, a silicon substrate. In the embodiments of the present disclosure, a case in which the substrate 20 is a silicon substrate will be taken as an example for description below. In other embodiments, the substrate 20 may also be a gallium nitride substrate, a gallium arsenide substrate, a gallium carbide substrate, a silicon carbide substrate, an SOI substrate, or other semiconductor substrates. The substrate 20 is configured to support a device structure thereon. After an active region, a buried word line structure, and an isolation region 21 located outside the active region are formed inside the substrate 20, an oxide material (such as silicon dioxide), a nitride material (such as silicon nitride), or an oxynitride material (such as silicon oxynitride) may be deposited on the top surface of the substrate 20 by a chemical vapor deposition process, a physical vapor deposition process, or an atomic layer deposition process to form the dielectric layer 22 covering the top surface of the substrate 20. Then, a material, such as metal tungsten or TiN, may be deposited on the dielectric layer 22 by an atomic layer deposition process to form the bit line (i.e., the signal line 10) extending along the second direction D2, as shown in FIG. 7.

In some embodiments, specific steps of forming the contact structure extending along the first direction include:
forming an insulating layer 80 covering the signal line 10;
etching the insulating layer 80 to form a contact groove 70 exposing at least the signal line 10, as shown in FIG. 8; and
forming, in the contact groove 70, the contact structure 11 in contact with and electrically connected to the signal line 10 exposed, as shown in FIG. 9.

In some embodiments, specific steps of forming the contact groove 70 exposing at least the signal line 10 include:
etching the insulating layer 80 using the signal line 10 as an etching stop layer and over-etching the dielectric layer 22 to form the contact groove 70 at least penetrating through the dielectric layer 22 along the first direction D1.

In some embodiments, the substrate 20 further includes therein an active region and an isolation region 21 located outside the active region; the specific step of forming the contact groove 70 exposing at least the signal line 10 includes:
etching the insulating layer 80 using the signal line 10 as an etching stop layer and over-etching the isolation region 21 to form the contact groove 70 at least extending to the inside of the isolation region 21 along the first direction D1.

In some embodiments, the signal line 10 extends along a second direction D2, and the second direction D2 is parallel to the top surface of the substrate 20. The specific step of forming the contact groove 70 exposing at least the signal line 10 includes:
etching the insulating layer 80 to form a first etched groove 701 exposing a top surface of the signal line 10 and a second etched groove 702 exposing a side wall of the signal line 10. The first etched groove 701 is in communication with the second etched groove 702, and a plurality of the second etched grooves 702 are disposed on two opposite sides of the first etched groove 701 along a third direction D3, the first etched groove 701 and the second etched grooves 702 jointly form the contact groove 70, the third direction is parallel to the top surface of the substrate 20, and the second direction D2 intersects with the third direction D3.

Specifically, after forming a plurality of the signal lines 10 that are spaced apart along the third direction D3 and extend along the second direction D2, a silicon dioxide or a silicon nitride material is deposited on the signal lines 10 to form an insulating layer 80 continuously covering the plurality of the signal lines 10 spaced apart along the third direction D3 and the top surface of the dielectric layer 22, so as to prevent the external environment from affecting the signal lines 10 (e.g., to prevent the oxide in the external environment from oxidizing the signal lines 10). Then, an appropriate mask plate may be selected according to the preset shape of the contact groove 70, and at least the insulating layer 80 and the dielectric layer 22 are etched by a dry etching process to form the contact groove 70 at least penetrating through the insulating layer 80 along the first direction D1 and exposing the top surface of the signal line 10 and the side wall of the signal line 10, as shown in FIG. 8. In some embodiments of the present disclosure, in the etching process, the insulating layer 80 may be etched using the signal line 10 as an etching stop layer and the dielectric layer 22 and the isolation region 21 may be over-etched, so as to form the contact groove 70 at least penetrating through the dielectric layer 22 along the first direction D1 and extending to the inside of the isolation region 21, such that the contact groove 70 extending to the inside of the isolation region 21 can be formed by a one-step etching process, which further reduces the manufacturing process of the semiconductor structure. In some embodiments of the present disclosure, the contact groove 70 extends to the inside of the isolation region 21, such that the area of the signal line 10 that is exposed by the contact groove 70 can be further increased, the contact area between the contact structure 11 subsequently formed in the contact groove 70 and the signal line 10 is further increased, and the contact resistance between the contact structure 11 and the signal line 10 is reduced; at the same time, the stable contact and electrical connection between the contact structure 11 formed in the contact groove 70 and the side wall of the signal line 10 is ensured, and the overall stability of the contact structure 11 is improved.

In some embodiments, a plurality of the signal lines 10 are spaced apart along a third direction D3, a first spacing P is present between adjacent signal lines 10 along the third direction D3, the third direction D3 is parallel to the top surface of the substrate 20, and the second direction D2 intersects with the third direction D3. The specific step of forming the contact groove 70 exposing the signal line 10 and extending at least into the dielectric layer 22 includes:
etching the insulating layer 80 and the dielectric layer 22 to form a plurality of contact grooves 70 exposing the plurality of the signal lines 10 in a one-to-one correspondence, where half of an inner diameter of the contact groove is less than one third of the first spacing P. With this structure, in one aspect, it can be ensured that two adjacent contact grooves 70 along the third direction D3 are fully isolated, and signal crosstalk between two adjacent contact structures 11 subsequently formed is fully reduced; in another aspect, it also helps to control the size of the semiconductor structure, thereby laying a foundation for miniaturization of the semiconductor structure.

In some embodiments, a depth of the isolation region 21 along the first direction D1 inside the substrate 20 is a first depth H1, and a depth of the contact groove 70 extending to the isolation region 21 is less than or equal to a quarter of the first depth H1.

Specifically, by defining the depth of the contact groove 70 extending to the isolation region 21 to be less than or equal to a quarter of the first depth H1, in one aspect, the etching depth when the contact groove 70 is formed can be reduced, thereby further simplifying the process of forming the contact groove and improving the efficiency of forming the contact structure 11; in another aspect, the problem of current leakage caused by the contact structure 11 subsequently formed inside the contact groove 70 being too close to the substrate 20 below the isolation region 21 (i.e., the well region inside the substrate 20) can also be avoided, thereby further ensuring the yield of the semiconductor structure.

In some embodiments, two contact grooves 70 electrically connected to two adjacent signal lines 10 are disposed opposite to each other along the second direction D2. In one aspect, the distance between two adjacent contact grooves 70 along the third direction D3 can be further increased, thereby further reducing the capacitive coupling effect between two adjacent contact structures 11 along the third direction D3; in another aspect, the process window for forming the contact grooves 70 can be widened, the manufacturing difficulty of the contact grooves 70 can be reduced, and the manufacturing efficiency of the semiconductor structure can be improved.

This embodiment is described by taking a case in which, in the first direction D1, the bottom surface of the contact groove 70 is located below the bottom surface of the signal line 10 as an example. In other embodiments, the bottom surface of the contact groove 70 may also be flush with the bottom surface of the signal line 10, thereby ensuring an increase in the contact area between the contact structure 11 and the signal line 10, and at the same time, reducing the etching depth of the contact groove 70 and improving the manufacturing efficiency of the semiconductor structure.

In some embodiments, after forming the contact structure 11 extending along the first direction D1, the method further includes the following step:
forming, on a top surface of the contact structure 11, an interconnect metal layer 12 electrically connected to the contact structure 11, where a width of the interconnect metal layer 12 is less than a width of the top surface of the contact structure 11.

Specifically, after the contact structure 11 is formed, an insulating material, such as silicon dioxide, may be deposited on the top surface of the contact structure 11 by a chemical vapor deposition process, a physical vapor deposition process, or an atomic layer deposition process, to form a cap layer that covers the contact structure 11 and the insulating layer 80, thereby avoiding impact, such as oxidation, caused by an external environment on the contact structure 11. Then, the cap layer may be etched by a dry etching process to form an interconnect groove exposing the top surface of the contact structure 11. A conductive material, such as metal tungsten or copper, is deposited in the interconnect groove to form the interconnect metal layer 12 electrically connected to the contact structure 11. In an example, since the width of the contact structure 11 on the top surface of the signal line 10 along the third direction (i.e., the first width L1) is greater than the width of the signal line 10 along the third direction D3 (i.e., the second width L2), when the interconnect metal layer 12 is formed, the process window for forming the interconnect groove can be widened, and the manufacturing process of the interconnect metal layer 12 can be simplified. The interconnect metal layer 12 is configured to electrically connect the contact structure 11 and a peripheral control circuit.

In the semiconductor structure and the method for forming the same provided by some embodiments of the present disclosure, the contact structure electrically connected to the signal line is arranged so that the contact structure is disposed partially around the end part of the signal line, so the contact area between the contact structure and the signal line can be increased, the contact resistance between the contact structure and the signal line can be reduced, and the performance of the semiconductor structure can be improved. In the method for forming a semiconductor structure provided in some embodiments of the present disclosure, in the process of forming the contact structure, only the shape of the mask needs to be changed, and no additional process step needs to be added, so the manufacturing efficiency of the semiconductor structure can be ensured while the performance of the semiconductor structure is improved.

The foregoing only illustrates preferred embodiments of the present disclosure, and it should be noted that a number of improvements and modifications may be made by those of ordinary skill in the art without departing from the principles of the present disclosure, and these improvements and modifications shall be considered as falling within the protection scope of the present disclosure.

What is claimed is:

1. A semiconductor structure, comprising:
a substrate;
a signal line located on the substrate; and
a contact structure extending along a first direction, wherein contact structure is disposed partially around an end part of the signal line, the contact structure is in contact with and electrically connected to the signal line, and the first direction is perpendicular to a top surface of the substrate.

2. The semiconductor structure according to claim 1, wherein the signal line extends along a second direction, and the second direction is parallel to the top surface of the substrate;
the contact structure covers a top surface of the signal line and is disposed around part of a side wall of the signal line.

3. The semiconductor structure according to claim 2, wherein a width of the contact structure located on the top surface of the signal line along a third direction is a first width, a width of the signal line along the third direction is a second width, the first width is greater than or equal to the second width, the third direction is parallel to the top surface of the substrate, and the second direction intersects with the third direction.

4. The semiconductor structure according to claim 3, wherein the contact structure comprises:
a main body portion located on the signal line and being in contact with and electrically connected to the signal line; and
an extension portion disposed at an end part of the main body portion along the third direction and being in contact with and electrically connected to the main body portion, wherein the extension portion covers the side wall of the signal line.

5. The semiconductor structure according to claim 4, wherein a plurality of extension portions are spaced apart along the second direction, and are all in contact with and electrically connected to the main body portion;
the plurality of extension portions are disposed on two opposite sides of the main body portion along the third direction.

6. The semiconductor structure according to claim 2, wherein the contact structure comprises:
a main body portion located on the signal line and being in contact with and electrically connected to the signal line; and
an extension portion disposed at an end part of the main body portion along the second direction and being in contact with and electrically connected to the main body portion, wherein the extension portion covers an end surface of the signal line.

7. The semiconductor structure according to claim 3, wherein a plurality of signal lines are spaced apart along the third direction, a plurality of contact structures are electrically connected to the plurality of signal lines in a one-to-one correspondence, and each of the plurality of contact structures is disposed partially around an end part of the signal line electrically connected thereto;
two of the plurality of contact structures electrically connected to two adjacent signal lines are staggered along the third direction.

8. The semiconductor structure according to claim 7, wherein the plurality of signal lines are sequentially arranged in the third direction, and the contact structure electrically connected to an odd-numbered signal line and the contact structure electrically connected to an even-numbered signal line are disposed opposite to each other along the second direction.

9. The semiconductor structure according to claim 2, wherein in the first direction, a bottom surface of the contact structure is located below a bottom surface of the signal line.

10. The semiconductor structure according to claim 1, wherein the substrate further comprises therein an active region and an isolation region located outside the active region;
the contact structure extends to inside of the isolation region along the first direction.

11. The semiconductor structure according to claim 10, wherein a depth of the isolation region inside the substrate along the first direction is a first depth, a depth of the contact structure extending to the isolation region along the first direction is a second depth, and the second depth is less than the first depth.

12. A method for forming a semiconductor structure, comprising:
providing a substrate;
forming a signal line on the substrate; and
forming a contact structure extending along a first direction, wherein the contact structure is partially disposed around an end part of the signal line, the contact structure is in contact with and electrically connected to the signal line, and the first direction is perpendicular to a top surface of the substrate.

13. The method for forming a semiconductor structure according to claim 12, wherein specific steps of forming the contact structure extending along the first direction ctheomprise:
forming an insulating layer covering the signal line;
etching the insulating layer to form a contact groove exposing at least the signal line; and
forming, in the contact groove, the contact structure in contact with and electrically connected to the signal line exposed.

14. The method for forming a semiconductor structure according to claim 13, wherein the substrate further comprises therein an active region and an isolation region located outside the active region; a specific step of forming the contact groove exposing at least the signal line comprises:
etching the insulating layer using the signal line as an etching stop layer and over-etching the isolation region to form the contact groove at least extending to inside of the isolation region along the first direction.

15. The method for forming a semiconductor structure according to claim 13, wherein the signal line extends along a second direction, and the second direction is parallel to the top surface of the substrate; a specific step of forming the contact groove exposing at least the signal line comprises:
etching the insulating layer to form a first etched groove exposing a top surface of the signal line and a second etched groove exposing a side wall of the signal line, wherein the first etched groove is in communication with the second etched groove, a plurality of second etched grooves are disposed on two opposite sides of the first etched groove along a third direction, the first etched groove and the plurality of second etched grooves jointly form the contact groove, the third direction is parallel to the top surface of the substrate, and the second direction intersects with the third direction.

16. The method for forming a semiconductor structure according to claim 14, wherein a depth of the isolation region inside the substrate along the first direction is a first depth, and a depth of the contact groove extending to the isolation region is less than or equal to a quarter of the first depth.

17. The method for forming a semiconductor structure according to claim 14, further comprising: forming, on a top surface of the contact structure, an interconnect metal layer electrically connected to the contact structure, wherein a width of the interconnect metal layer is less than a width of the top surface of the contact structure.

18. The method for forming a semiconductor structure according to claim 17, further comprising: forming a cap layer covering the contact structure and the insulating layer after forming the contact structure.
